(19) United States
(12) Patent Application Publication
(10) Pub. No.: US 2007/0211415 A1
(43) Pub. Date: Sep. 13, 2007

(54) HOLDING CASE USABLE WITH AN INFORMATION PROCESSING APPARATUS

(76) Inventors: Joung-shin SEO, Seoul (KR); Jin Kwon, Seoul (KR)

Correspondence Address: STANZIONE & KIM, LLP, 919 18TH STREET, N.W., SUITE 440, WASHINGTON, DC, 20006, US

(21) Appl. No.: 11/611,201

(22) Filed: Dec. 15, 2006

(30) Foreign Application Priority Data
Mar. 8, 2006 (KR) 2006-21953

(51) Int. Cl. H05K 5/00; G06F 1/16

(52) U.S. Cl. 361/679; 361/683

(57) ABSTRACT

A holding case to support an information processing apparatus that includes a first cover having a holding part that protrudes from a surface of the first cover to detachably support the information processing apparatus, a second cover that can be foldably coupled with the first cover, and a third cover that can be foldably coupled with one of the first cover and the second cover.

### CROSS-REFERENCE TO RELATED APPLICATIONS

This application claims priority from Korean Patent Application No.2006-0021953, filed on Mar. 8, 2006, in the Korean Intellectual Property Office, the disclosure of which is incorporated herein in its entirety by reference.

### BACKGROUND OF THE INVENTION

1. Field of the Invention

The present general inventive concept relates to a holding case usable with an information processing apparatus, and more particularly, to a holding case usable with an information processing apparatus to enhance portability and a user's convenience.

2. Description of the Related Art

Generally, an information processing apparatus can comprise a computer, an MP3 player, a PDA (personal digital assistant), a portable telephone, a digital camera, an electronic frame, a PMP (portable multimedia player), etc.

Among the information processing apparatuses, the computer especially requires a peripheral device such as an ODD (optical disk drive), a floppy disk drive, a card type record media reproducing device, a tape type record media reproducing device, etc. The computer may be classified into a desk top computer, a portable computer, etc. The portable computer has typically a small weight and size so that a user can easily carry it.

Recently, the portable computer has become miniaturized, and had various functions such as a tablet function, a television function such as a DMD (digital multimedia broadcasting), etc., as well as a basic function. The portable computer has become more convenient to be provided with an input device, such as a pen, a keyboard, etc.

Thus, there is a need for a carrying case usable with the information processing apparatus and/or the peripheral device, so that a user may easily carry and preserve the information processing apparatus and/or the peripheral device by using such a case.

### SUMMARY OF THE INVENTION

The present general inventive concept provides a holding case usable with an information processing apparatus to enhance portability and a user's convenience.

Additional aspects and advantages of the present general inventive concept will be set forth in part in the description which follows and, in part, will be obvious from the description, or may be learned by practice of the general inventive concept.

The foregoing and/or other aspects and utilities of the present general inventive concept can be achieved by providing a holding case to support an information processing apparatus, comprising: a first cover comprising a holding part to protrude from a surface of the first cover to detachably support the information processing apparatus; a second cover foldably coupled with the first cover; and a third cover foldably coupled with one of the first cover and the second cover.

The holding part may comprise an upper supporting member and a lower supporting member respectively provided at an inner upper part and an inner lower part of the first cover to respectively support an upper end part and a lower end part of the information processing apparatus, and a side supporting member provided at inner opposite sides of the first cover to have elasticity.

The second cover may comprise a peripheral holding part provided at an inner upper part and an inner lower part of the second cover to detachably support a peripheral device of the information processing apparatus.

The holding case may further comprise a locking part to maintain folding of the first cover and the second cover together when the third cover is folded between the first cover and the second cover.

The holding case may further comprise a rear supporting member provided at an outer part of the first cover to support the information processing apparatus at various angles when the first cover is unfolded.

The first, second and third covers can each be formed in a planar shape.

The foregoing and/or other aspects and utilities of the present invention general inventive concept can also be achieved by providing a holding case to support an information processing apparatus, comprising: a first cover including at least one first set of opposing holding parts that protrude from a surface of the first cover to detachably support the information processing apparatus; a second cover including at least one second set of opposing holding parts that protrude from a surface of the second cover to detachably support a peripheral device, the second cover foldably attachable to the first cover; and a locking unit disposed at the rear portion of each of the first cover and the second cover to lock the first cover and the second cover in a folded state.

The second cover can further include a first portion and a second portion foldable with respect to each other, the first portion having the at least one second set of opposing holding parts disposed thereon and the second portion foldable over the first portion to provide a barrier between the information processing apparatus and the peripheral device when the first cover and the second cover are folded over each other.

The locking unit may comprise: at least one first engaging part on a rear portion of the first cover; and at least one second engaging part on a rear potion of the second cover to lockingly engage with the respective first engaging part.

The locking unit may further comprise: a locking part main body connected to the second cover at one end and containing the at least one second engaging part at another end to lockingly engage with the respective at least one first engaging part.

The at least one first a first set of opposing holding parts may comprise: a lower holding part extending along a length of an upper portion of the first cover; an upper holding part extending along a length of a lower portion of the first cover; and at least one pair of side holding parts, each pair disposed at opposite sides of the first cover to face each other and movable toward and away from each other to accommodate information processing apparatuses having different widths.

The at least one first a first set of opposing holding parts may comprise: a lower holding part extending along a length of an upper portion of the first cover; an upper holding part extending along a length of a lower portion of the first cover; and at least one pair of side holding parts, each pair disposed at opposite sides of the first cover to face each other and movable toward and away from each other to accommodate information processing apparatuses having different widths.

The first cover may further comprise: a rear supporting member comprising: a first portion connected to a rear portion of the first cover; a second portion connected at one end to the first potion and to rotate with respect to the first potion at different angles to support the first cover at different angles with respect to a surface on which the holding case is placed.

The foregoing and/or other aspects and utilities of the present invention general inventive concept can also be achieved by providing a holding case to support an information processing apparatus, comprising: a first cover including at least one first set of opposing holding parts that protrude from a surface of the first cover to detachably support the information processing apparatus; and a second cover including at least one second set of opposing holding parts that protrude from a surface of the second cover to detachably support a peripheral device, the second cover including a first portion foldably attachable to the first cover at a first side and having a same size as the first cover and a second portion that extends from a second side to be foldable between the first cover and the second cover to be disposed between the information processing apparatus and the peripheral device.

The first cover may further include a first locking portion, and the second cover further includes a second locking portion connected to the first portion thereof to extend to the first cover to be locked to the first locking portion to maintain the first cover and the second cover in the folded state.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a perspective view illustrating a holding case according to an embodiment of the present general inventive concept;

FIG. 2 is an exploded perspective view illustrating the holding case in FIG. 1;

FIG. 3 is a sectional view taken along line IV-IV in FIG. 1;

FIG. 4 is a sectional view taken along line III-III in FIG. 1;

FIG. 5 is a sectional view illustrating a mounting process of a portable computer in FIG. 1; and

FIGS. 6A to 6E are perspective views illustrating folding processes of the holding case in FIG. 1.

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to the like elements throughout. The embodiments are described below in order to explain the present general inventive concept by referring to the figures.

In a holding case usable with an information processing apparatus according to the present general inventive concept, the information processing apparatus is provided as a portable computer. However, the information processing apparatus can comprise an MP3 player, a PDA (personal digital assistant), a portable telephone, a digital camera, an electronic frame, a PMP (portable multimedia player), etc.

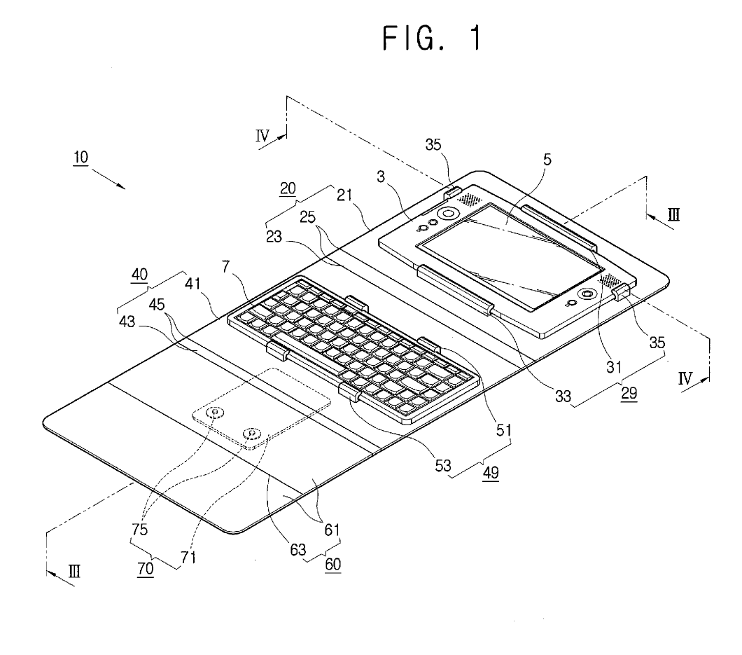

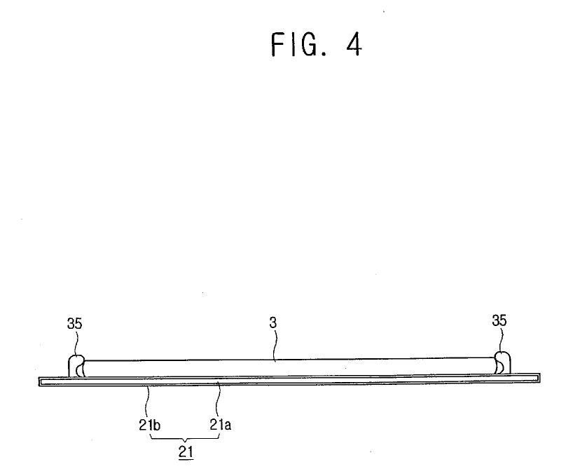

As illustrated in FIGS. 1 to 4, a holding case usable with an information processing apparatus 10 includes a first cover 20 provided in a planar shape and including a holding part 29 that protrudes to detachably mount a portable computer 3 to a surface thereof, a second cover 40 provided in a planar shape and foldably coupled with the first cover 20, and a third cover 60 provided in a planar shape and foldably coupled with one of the first cover 20 and the second cover 40. Also, the holding case 10 includes a locking part 70 that maintains a folded state of the first cover 20 and the second cover 40 when the third cover 60 is folded between the first cover 20 and the second cover 40.

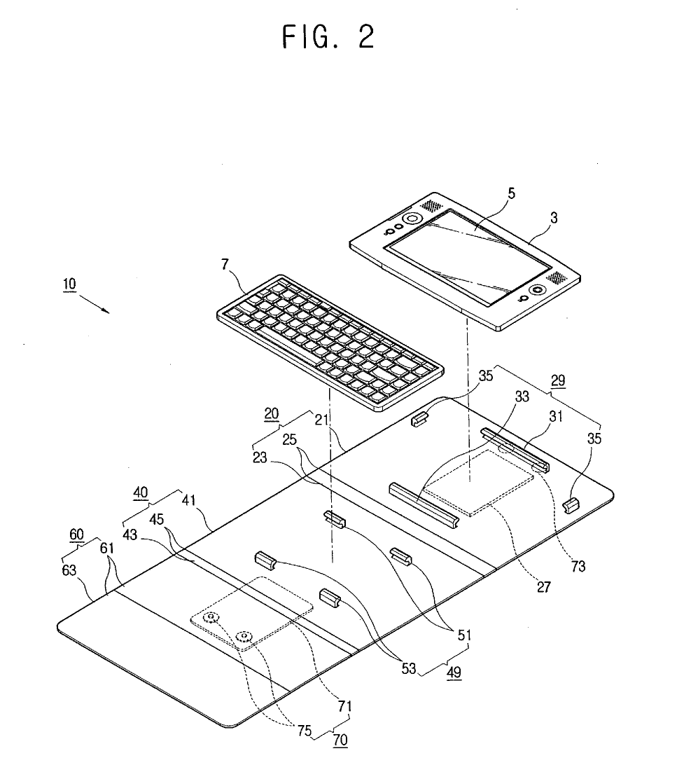

Referring to FIGS. 1 and 2, the portable computer 3 can include a display part 5 that displays an image, and an operation part (not illustrated) provided in a front thereof through which a user can operate the portable computer 3. The portable computer 3 may comprise a television function such as a DMD (digital multimedia broadcasting) capable of receiving a satellite broadcasting signal, etc., as well as a typical information processing function. The portable computer 3 may comprise a tablet function capable of being input by a pen, and which can be operated by a peripheral device 7, such as a keyboard, as necessary.

The peripheral device 7 supports the portable computer 3. The peripheral device 7 may comprise an input part such as a keyboard, or other various known devices. The peripheral device 7 may be electrically connected with the portable computer 3 through a cable (not illustrated), a wireless system, etc.

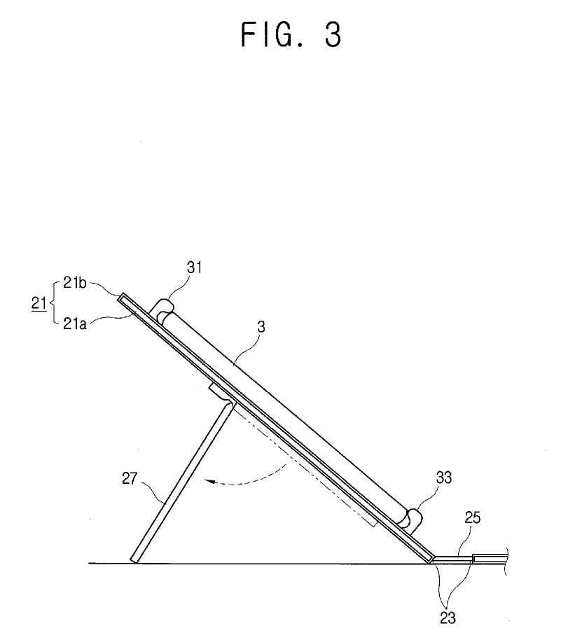

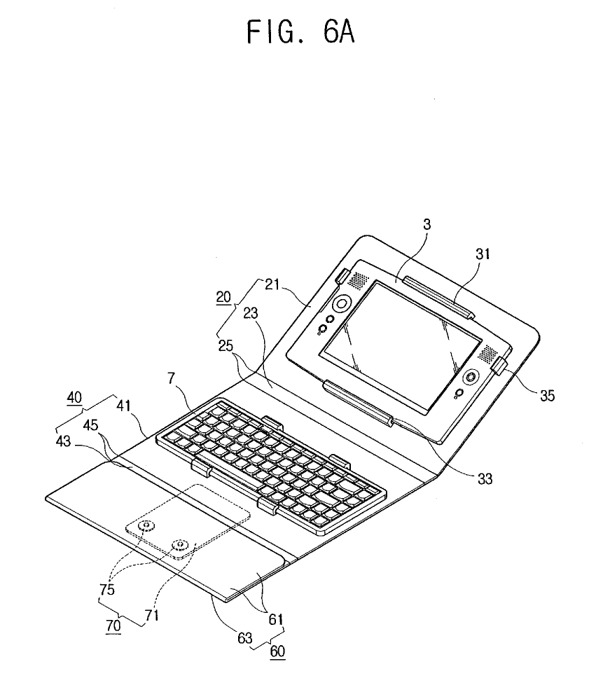

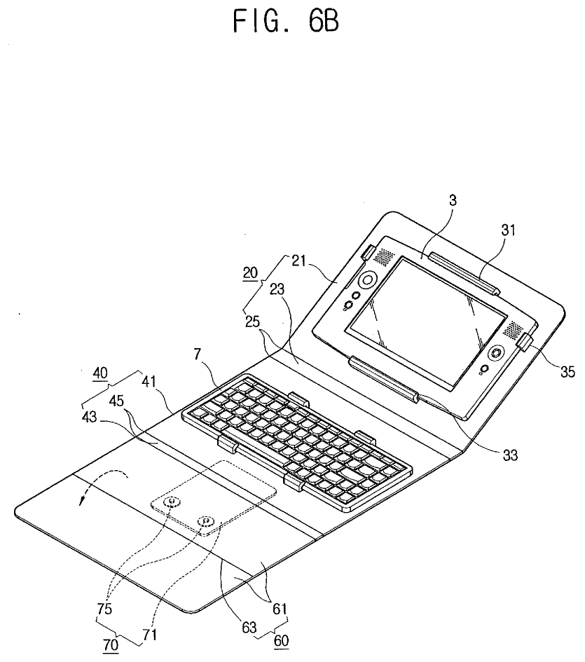

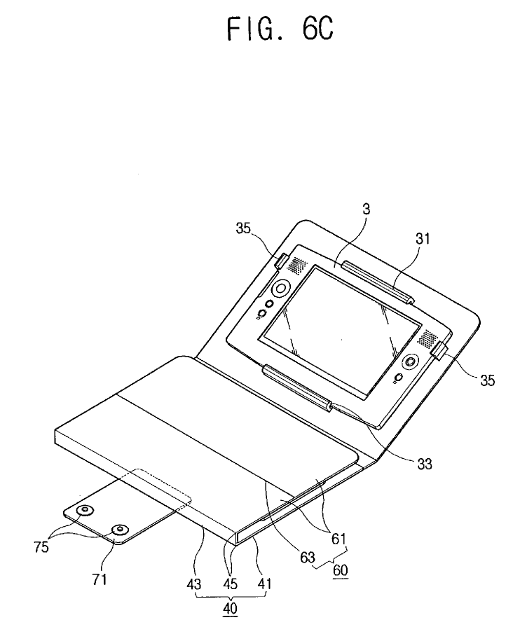

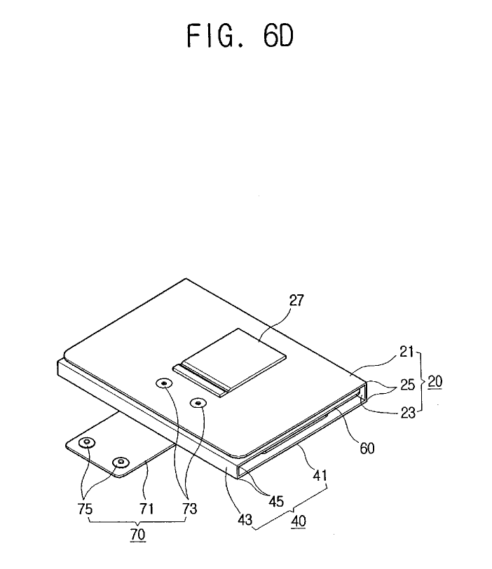

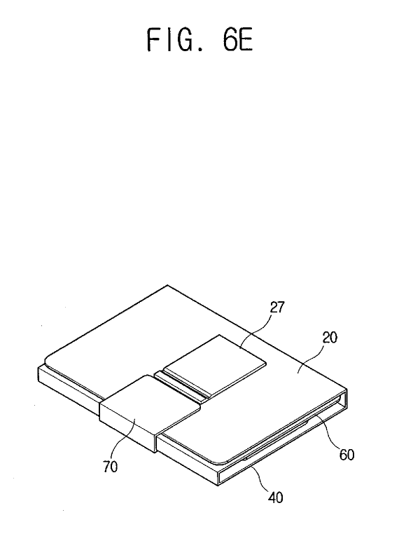

The first cover 20 includes the holding part 29 to protrude from a surface of the first cover 20 to detachably mount the portable computer 3 to the first cover 20 in a perpendicular direction with respect to the surface thereof. The holding part 29 may be formed so that the portable computer 3 is detachably mounted to the first cover 20 in other directions. The first cover 20 includes a planar first cover main body 21, and a first cover connecting part 23 to extend from the first cover main body 21 to be coupled with the second cover 40. The first cover 20 is preferably formed in a planar shape. As illustrated in FIG. 3, the first cover 20 may comprise an inner member 21a formed of a plastic material having a light weight and a predetermined strength, and an outer member 21b to surround the inner member 21a and formed of vinyl or leather having an elegant appearance. Alternatively, the outer member 21b of the first cover 20 may be formed of other known materials. Referring to FIG. 2, the first cover 20 further includes a rear supporting member 27 provided at an outer part thereof to support the portable computer 3 at a desired angle when the first cover 20 is unfolded. Referring to FIGS. 2 and 6D, the first cover 20 further includes a first engaging part 73 to lock the first cover 20 and the second cover 40 together when the first cover 20 and the second cover 40 are folded.

The first cover connecting part 23 includes a first cover hinge 25 to connect the first cover 20 and the second cover 40 so that the first cover 20 and the second cover 40 are smoothly folded. As illustrated in FIG. 3, the first cover hinge 25 comprises the outer member 21b without the inner member 21a. Thus, a user can conveniently fold the first cover 20 and the second cover 40.

Referring to FIG. 3, the rear supporting member 27 is provided to an outer part of the first cover 20, and supports the portable computer 3 when the first cover 20 is unfolded from the second cover 40. Furthermore, the rear supporting member 27 is provided at the first cover 20 so that the portable computer 3 can be positioned at various inclined angles. Thus, a user can view the portable computer 3 at various viewing angles as desired.

The holding part 29 protrudes from an inner surface of the first cover 20 to detachably support the portable computer 3 with respect to the inner surface of the first cover 20. As illustrated in FIG. 1, the holding part 29 includes at least one upper supporting member 31 and at least one lower supporting member 33 respectively provided at an inner upper part and an inner lower part of the first cover 20 to respectively support an upper end part and a lower end part of the portable computer 3. Also, the holding part 29 can include side supporting members 35 provided at the opposite inner sides of the first cover 20 to elastically bias the portable computer 3 toward the first cover 20 on which the portable computer 30 is mounted. Thus, the portable computer 3 can be easily mounted to the first cover 20, and can be simply detached therefrom by pushing the side supporting members 35 in opposite directions.

Referring to FIG. 2, the upper supporting member 31 and the lower supporting member 33 are respectively coupled to the upper and lower parts of the inner side of the first cover 20 to respectively support upper and lower end parts of the portable computer 3. The upper supporting member 31 and the lower supporting member 33 may be respectively provided in singular or plural. In other words, there may be provided one or more of each of the upper supporting member 31 and the lower supporting member 33. Referring to FIG. 3, the upper supporting member 31 and the lower supporting member 33 can have concave contact surfaces to contact the portable computer 3 mounted to the first cover 20 to correspond to a convex shape of the portable computer 3. Also the upper supporting member 31 and the lower supporting member 33 can have a predetermined elasticity to expand and contract when the portable computer 3 is mounted and detached from the first cover 20. Thus, the upper supporting member 31 and the lower supporting member 33 can prevent the portable computer 3 from being separated from the surface of the first cover 20.

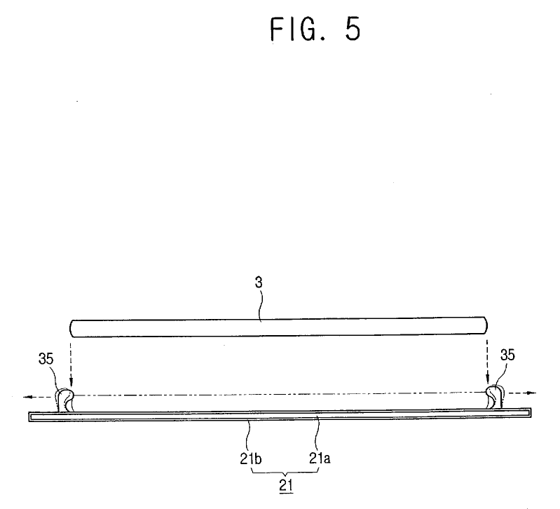

Referring to FIG. 5, the side supporting members 35 are coupled to the opposite inner sides of the first cover 20 to elastically expand and contract in a planar direction of the first cover 20. The side supporting members 35 can be provided as a pair thereof. Alternatively, the side supporting members 35 may have a size and/or a number thereof depending on the size, thickness, etc., of the portable computer 3. Thus, as illustrated in FIG. 5, a user can easily mount and detach the portable computer 3 by pushing the side supporting members 35 outward.

Referring to FIGS. 1 and 2, the second cover 40 is coupled to the first cover 20 to be folded therewith. The second cover 40 includes a peripheral holding part 49 provided at upper and lower parts of an inner side of the second cover 40 to support the peripheral device 7. The second cover 40 includes a second cover main body 41, and a second cover connecting part 43 to extend from the second cover main body 41 to be coupled with the third cover 60. The second cover 40 can be formed in a planar shape. The second cover 40 comprises an inner member (not illustrated) formed of a plastic material having a light weight and a predetermined strength, and an outer member surrounding the inner member and formed of vinyl or leather having an elegant appearance. Alternatively, the outer member of the second cover 40 may be formed of other known materials. The second cover 40 further includes a second engaging part 75 to lock the first cover 20 and the second cover 40 together when the first cover 20 and the second cover 40 are folded.

The second cover connecting part 43 includes a second cover hinge 45 to connect the second cover 40 and the third cover 60 so that the second cover 40 and the third cover 60 can be smoothly folded together. The second cover hinge 45 comprises the outer member without the inner member. Thus, a user can conveniently fold the second cover 40 and the third cover 60 to overlap each other.

Referring to FIG. 2, the peripheral holding part 49 protrudes from upper and lower parts of an inner side of the second cover 40 to detachably support the peripheral device 7 of the portable computer 3. The peripheral holding part 49 includes at least one peripheral upper supporting member 51 and at least one peripheral lower supporting member 53 respectively provided at the upper and lower parts of the second cover 40. The peripheral holding part 49 is provided at the second cover 40 to have a predetermined elasticity to expand and contract when the peripheral device 7 is mounted and detached therefrom. Thus, the peripheral device 7 can be prevented from being separated from the surface of the second cover 40.

Referring to FIGS. 1 and 2, the third cover 60 is illustrated as being provided in a planar shape, and is coupled to one of the first cover 20 and the second cover 40 to be folded therewith. The third cover 60 includes a planar third cover main body 61. The third cover 60 may further include a third cover hinge part 63 provided at a central part of the third cover main body 61 so that the third cover 60 can be folded as desired. Thus, when the holding case 10 is folded, the third cover 60 can be folded to be interposed between the first cover 20 and the second cover 40, thereby preventing the portable computer 3 from contacting the peripheral device 7. In other words, the third cover 60 can provide a cushioning between the first cover 20 and the second cover 40, thus providing a cushioning between the portable computer 30 and the peripheral device 7.

The locking part 70 maintains the first and second covers 20 and 40 to be folded together when the first and second covers 20 and 40 are folded. The locking part 70 includes a locking part main body 71 capable of being folded, the first engaging part 73 being provided at the first cover 20 to have a recessed snap part, and the second engaging part 75 being provided with a prominent snap part to interlock with the recessed snap part of the first engaging part 73. The locking part 70 may be provided as a protrusion and a groove, a hook and a hook engaging part, or other various known means.

Hereinafter, an operation of the holding case 10 for the portable computer 3 will be described while referring to FIGS. 6A to 6E.

Referring to FIG. 6A, the holding case 10 is unfolded. The portable computer 3 is mounted to the first cover 20, and the rear supporting member 27 (see FIGS. 6D and 6E) supports the first cover 20 with respect to an installation surface, such as a desk, to have a predetermined inclined angle therebetween. The second cover 40 has the peripheral device 7 mounted thereto, and is seated on the installation surface in front of the first cover 20. The third cover 60 is folded through the third cover hinge part 63. Thus, a user can use the portable computer 3 and the peripheral device 7 electrically connected together to perform work. Then, referring to FIG. 6B, the third cover 60 becomes unfolded through the third cover hinge part 63.

Referring to FIG. 6C, the third cover 60 can be folded with respect to the second cover hinge 45 to be positioned over the second cover 20 to which the peripheral device 7 is mounted. Referring to FIG. 6D, the rear supporting part 27 of the first cover 20 can be positioned parallel with the first cover 20, and the first cover 20 is folded with respect to the first cover hinge 25 to be positioned over the third cover 60. Then, the locking part 70 attached to the second cover 40 can be folded, and the first engaging part 73 of the first cover 20 can be engaged with the second engaging part 75 of the second cover 40 so that the portable computer 3 and the peripheral device 7 are supported inside the holding case 10. Thus, a user can conveniently fold and unfold the holding case 10, and the portable computer 3 and the peripheral device 7 can be simply carried or kept in the state that the holding case 10 is folded while and the portable computer 3 and the peripheral device 7 are not in contact with each other. Also, a user can easily detachably mount the portable computer 3 and the peripheral device 7 to the holding case 10 through the holding part 29 and the peripheral holding part 49, respectively.

The holding case according to the present general inventive concept can be conveniently folded and unfolded. Also, the holding case can be easily carried when folded, and can conveniently support the information processing apparatus when unfolded. Also, the information processing apparatus can be conveniently detachably mounted to the holding case as desired.

As described above, the present general inventive concept provides a holding case usable with an information processing apparatus easily carried when being folded, and conveniently supporting the information processing apparatus when being unfolded.

Also, the present general inventive concept provides a holding case usable with an information processing apparatus conveniently folded and unfolded.

Also, the present general inventive concept provides a holding case usable with an information processing apparatus that can be conveniently mounted and detached thereto and therefrom as desired.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. A holding case to support an information processing apparatus, comprising:
a first cover comprising a holding part that protrudes from a surface of the first cover to detachably support the information processing apparatus;
a second cover foldably coupled with the first cover; and
a third cover foldably coupled with one of the first cover and the second cover.

2. The holding case according to claim 1, wherein the holding part comprises:
an upper supporting member and a lower supporting member respectively provided to an inner upper part and an inner lower part of the first cover to respectively support an upper end part and a lower end part of the information processing apparatus, and
a side supporting member provided at inner opposite sides of the first cover to have elasticity.

3. The holding case according to claim 1, wherein the second cover comprises a peripheral holding part provided at an inner upper part and an inner lower part of the second cover to detachably support a peripheral device of the information processing apparatus.

4. The holding case according to claim 2, further comprising:
a locking part to maintain folding of the first cover and the second cover together when the third cover is folded between the first cover and the second cover.

5. The holding case according to claim 3, further comprising:
a locking part to maintain folding of the first cover and the second cover together when the third cover is folded between the first cover and the second cover.

6. The holding case according to claim 1, further comprising:
a rear supporting member provided at an outer part of the first cover to support the information processing apparatus at varying angles when the first cover is unfolded.

7. The holding case according to claim 1, wherein the first, second and third covers each are formed in a planar shape.

8. A holding case to support an information processing apparatus, comprising:
a first cover including at least one first a first set of opposing holding parts that protrude from a surface of the first cover to detachably support the information processing apparatus;
a second cover including at least one second set of opposing holding parts that protrude from a surface of the second cover to detachably support a peripheral device, the second cover foldably attachable to the first cover; and
a locking unit disposed at the rear portion of each of the first cover and the second cover to lock the first cover and the second cover in a folded state.

9. The holding case according to claim 8, wherein the second cover further includes a first portion and a second portion foldable with respect to each other, the first portion having the at least one second set of opposing holding parts disposed thereon and the second portion foldable over the first portion to provide a barrier between the information processing apparatus and the peripheral device when the first cover and the second cover are folded over each other.

10. The holding case according to claim 8, wherein the locking unit comprises:
at least one first engaging part on a rear portion of the first cover; and
at least one second engaging part on a rear potion of the second cover to lockingly engage with the respective first engaging part.

11. The holding case according to claim 10, wherein the locking unit further comprises:
a locking part main body connected to the second cover at one end and containing the at least one second engaging part at another end to lockingly engage with the respective at least one first engaging part.

12. The holding case according to claim 8, wherein the at least one first set of opposing holding parts comprises:
a lower holding part extending along a length of an upper portion of the first cover;
an upper holding part extending along a length of a lower portion of the first cover; and
at least one pair of side holding parts, each pair disposed at opposite sides of the first cover to face each other and movable toward and away from each other to accommodate information processing apparatuses having different widths.

13. The holding case according to claim 8, wherein the at least one second set of opposing holding parts comprises:
two lower holding parts disposed along a line at a lower portion of the second cover to hold an upper end of the peripheral device; and
two upper holding parts disposed along a line at an upper portion of the second cover to hold a lower end of the peripheral device.

14. The holding case according to claim 8, wherein the first cover further comprises:
a rear supporting member comprising:
a first portion connected to a rear portion of the first cover;
a second portion connected at one end to the first potion and to rotate with respect to the first potion at different angles to support the first cover at different angles with respect to a surface on which the holding case is placed.

15. A holding case to support an information processing apparatus, comprising:
a first cover including at least one first set of opposing holding parts that protrude from a surface of the first cover to detachably support the information processing apparatus; and
a second cover including at least one second set of opposing holding parts that protrude from a surface of the second cover to detachably support a peripheral device, the second cover including a first portion foldably attachable to the first cover at a first side and having a same size as the first cover and a second portion that extends from a second side to be foldable between the first cover and the second cover to be disposed between the information processing apparatus and the peripheral device.

16. The holding case according to claim 15, wherein
the first cover further includes a first locking portion, and
the second cover further includes a second locking portion connected to the first portion thereof to extend to the first cover to be locked to the first locking portion to maintain the first cover and the second cover in the folded state.
